(19) United States
(12) Patent Application Publication
(10) Pub. No.: US 2006/0234467 A1
(43) Pub. Date: Oct. 19, 2006

(54) Method of forming trench isolation in a semiconductor device

(76) Inventors: Toni D. Van Gompel, Austin, TX (US); Glenn C. Abeln, Austin, TX (US); Peter J. Beckage, Austin, TX (US); Kyle T. Gilliland, Pflugerville, TX (US); Mohamad Jahanbani, Austin, TX (US); James D. Burnett, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/106,822

(22) Filed: Apr. 15, 2005

(51) Int. Cl. H01L 21/76

(52) U.S. Cl. 438/424; 438/425

(57) ABSTRACT

Divots (35, 36) may particularly be a problem for isolation trenches (22, 24) that are shallow. These divots (35, 36) may have a negative impact on the performance of the integrated circuit (49). Densification heating may be used to reduce the size and/or depth of these divots (35, 36) during manufacturing. For example, densification heating may be done at a temperature of at least 1100 degrees Celsius for at least 10 minutes after filling the isolation trenches (22, 24) with dielectric material (30). This densification heating may improve the variation in threshold voltages of transistors (e.g. 48) on an integrated circuit (49), particularly SOI (silicon on insulator) devices. SRAM cells (50) in particular may benefit from this densification heating.

### RELATED APPLICATION

This is related to U.S. patent application Ser. No. 10/836,150, filed Apr. 30, 2004, entitled “Isolation Trench”, and assigned to the current assignee hereof.

### FIELD OF THE INVENTION

The present invention relates to semiconductor devices, and more particularly, to a method of forming trench isolation in a semiconductor device.

### RELATED ART

In the process of forming a semiconductor device, divots may be unintentionally formed in isolation trenches. These divots may particularly be a problem for trenches that are shallow. These divots may have a negative impact on the performance of the semiconductor device. It is therefore desirable to reduce the size and/or depth of these divots during manufacturing.

### BRIEF DESCRIPTION OF THE DRAWINGS

The present invention may be better understood, and its numerous objects, features, and advantages made apparent to those skilled in the art, by referencing the accompanying drawings.

FIGS. 1-10 of the drawings illustrate a series of partial cross-sectional views of a semiconductor device during various stages of manufacture of an integrated circuit according to one embodiment of the present invention.

FIG. 11 of the drawings illustrates an SRAM (static random access memory) cell which may be formed using the process illustrated in FIGS. 1-10.

The use of the same reference symbols in different drawings indicates similar or identical items. Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

FIG. 1 illustrates a wafer 10 having a handling layer 12. An insulating layer 14 overlies handling layer 12. Semiconductor material 16 overlies insulating material 14. Thermal oxide layer 18 overlies semiconductor material 16. Deposited nitride layer 20 overlies thermal oxide layer 18.

In one embodiment, handling layer 12 may be any semiconductor or insulating material. The thickness of handling layer 12 may be any thickness that prevents breakage, for example in the range of 710-740 micrometers. Insulating layer 14 may be any insulating material. In one embodiment, insulating material 14 comprises silicon oxide. Other semiconductor oxides may be used for layer 14. The thickness of insulating layer 14 may be any desired thickness, for example in the range of 140-200 nm. Semiconductor material 16 may be any semiconductor material, for example, silicon, germanium, etc. The thickness of semiconductor layer 16 may be any desired thickness, for example in the range of 10-150 nm. Thermal oxide 18 may be formed using any desired dielectric material. Thermal oxide is just one example. The thickness of thermal oxide 18 may be any desired thickness, for example in the range of 1-30 nm. The thickness of nitride layer may be any desired thickness, for example in the range of 50-250 nm.

Note that for one embodiment of wafer 10, layers 12, 14, and 16 form an SOI (silicon on insulator) substrate. Alternate embodiments may use a same material for layers 12 and 14, such as, for example, sapphire.

FIG. 1 illustrates layers 16, 18, and 20 in which isolation trenches 22, 24 have been formed. In one embodiment, trenches 22, 24 may be formed using an anisotropic etch. Alternate embodiments may form trenches 22, 24 in any desired manner. Although the depth of trenches 22, 24 may be any desired depth, one possible range for the depth of trenches 22, 24 is 10-150 nm. Alternate embodiments may use a trench depth of less than 150 nm. Note that depending upon the trench geometry, trenches 22 and 24 may be different portions of a same trench formed in wafer 10.

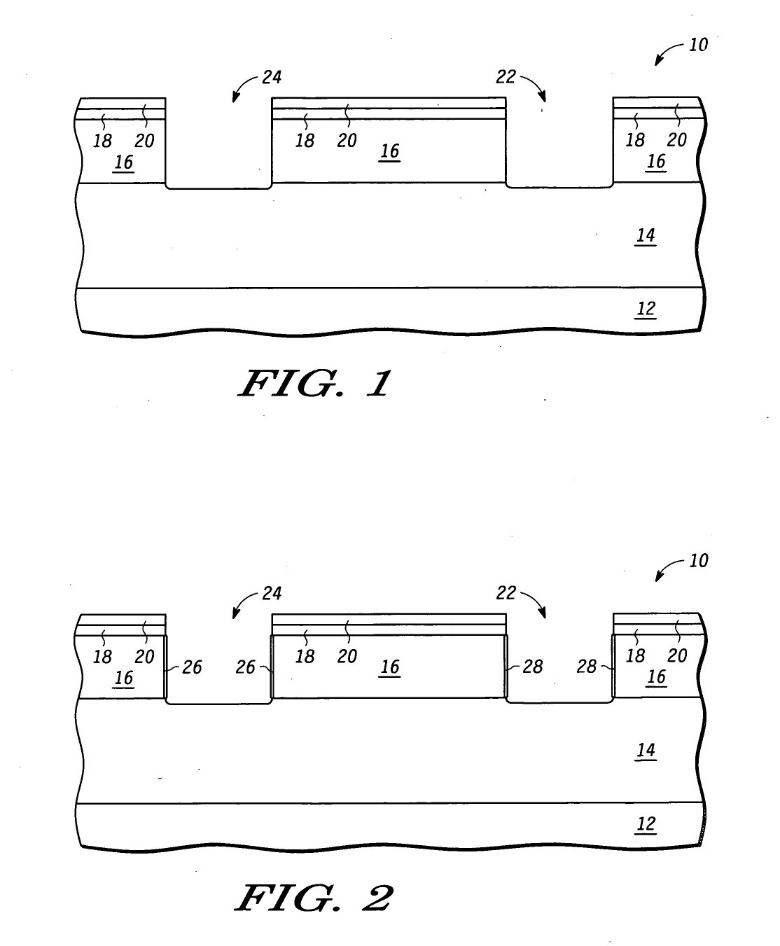

Referring to FIG. 2, thermal liners 26 are formed on the sidewalls of well 24 and thermal liners 28 are formed on the sidewalls of well 22. In one embodiment, thermal liners 26, 28 may be formed using a grown oxide. The thickness of thermal liners 26, 28 may be any desired thickness, for example in the range of 1-20 nm. Note that alternate embodiments may not form thermal liners 26 and 28 at this step in the process and may optionally skip the step illustrated in FIG. 2.

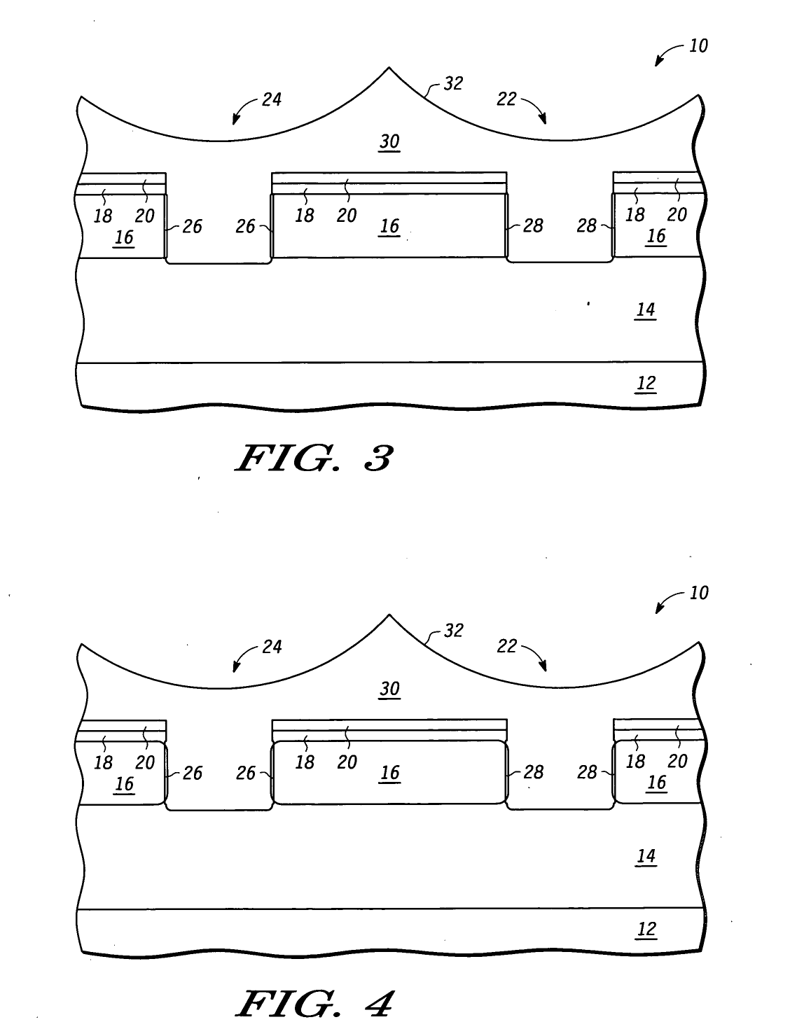

Referring to FIG. 3, dielectric material 30 is formed overlying layer 20 and in trenches 22, 24. In one embodiment, dielectric layer 30 may be silicon dioxide deposited in any desired manner, for example, HDP (high density plasma) oxide, TEOS (tetraethylorthosilicate) oxide, HTO (high temperature deposited) oxide, etc. The thickness of dielectric layer 30 may be any desired thickness, for example in the range of 150-700 nm, or alternately in the range of 250-400. In the illustrated embodiment, trenches 22, 24 are filled by layer 30. Note that in one embodiment, trench isolation in trench 24 comprises layer 30 and thermal liners 26. Similarly, in one embodiment, trench isolation in trench 22 comprises layer 30 and thermal liners 28. In alternate embodiments, filling trenches 22, 24 or forming a layer in trenches 22, 24 may comprise filling or forming a plurality of layers made of the same or different materials which are filled or formed in one or more steps. As one possible example, one or more of trenches 22, 24 may be filled using a plurality of layers or types of dielectric material.

Referring to FIG. 4, dielectric material 30 is densified by heating wafer 10 at a temperature of at least 1100 degrees C. (Celsius) for at least 10 minutes in an ambient gas comprising argon. In an alternate embodiment, dielectric material 30 may be densified by heating wafer 10 at a temperature of at least 1145 degrees C. In another embodiment, dielectric material 30 may be densified by heating wafer 10 at a temperature of at least 1150 degrees C. In another embodiment, dielectric material 30 may be densified by heating wafer at a temperature which falls within a range of 1100-1150 degrees C. In another embodiment, dielectric material 30 may be densified by heating wafer 10 at a temperature which falls within a range of 1100-1200 degrees C. In another embodiment, dielectric material 30 may be densified by heating wafer 10 at a temperature of at least 1000 degrees C. for at least 60 minutes. In another embodiment, dielectric material 30 may be densified by heating wafer 10 at a temperature of at least 1100 degrees C. for at least 10 minutes. In another embodiment, dielectric material 30 may be densified by heating wafer 10 at a temperature of at least 1150 degrees C. for at least 15 minutes.

Note that warpage of wafer 10 is a potential problem for SOI wafers. The use of high temperature processes (e.g. greater than 1000 degrees C.) generally causes wafer warpage problems for SOI wafers. However, due to recent improvements in the processes for manufacturing SOI wafers, it is now possible to use higher temperatures to process SOI wafers without causing serious wafer warpage problems. Note that using temperatures closer to 1100 degrees C. instead of temperatures at or below 1000 degrees C. for the densification heating process reduces the etch rate of trench isolation 30, 26 and 30, 28. A densification temperatures of 1000 degrees C. has virtually no effect on divot reduction 35 and 36 (see FIG. 9), while a densification temperature higher than 1000 and approaching 1100 degrees C. or higher significantly reduces the divots 35, 36.

In one embodiment, the ambient gas comprises argon for the densification heating step. Alternate embodiments may use any non-reacting gas in the ambient. For example, nitrogen may be non-reacting below a threshold temperature. One advantage to using argon over nitrogen is that argon remains non-reacting (i.e. inert) at the densification temperatures described herein. Nitrogen, on the other hand, may become reactive at densification temperatures above 950 degrees C. If the nitrogen becomes reactive, an interfacial barrier comprising nitrogen may be formed on exposed silicon and/or oxides (e.g. portions of the surface of layers 14, 16, 18, 20, 26, 28). This interfacial barrier may act to inhibit desired oxide growth during subsequent processing steps. This may be a significant problem. For example, significant undesirable leakage currents may result.

Note that the increase in density of dielectric material 30 causes layer 30 to etch more slowly, if at all, in response to etches that would have etched top surface 32 and layer 30 before densification. In one embodiment, the etches used at this stage are wet chemical etches, some of which comprise hydrofluoric acid.

Note that the heating of wafer 10 for densification purposes may also have an annealing effect on dielectric layer 30. In addition, this densification heating may also have an annealing effect on one or more of layers 16, 26, 28, 18, and 20.

Note that for some embodiments, thermal liners 26, 28 may be the same material as dielectric layer 30. If thermal liners 26, 28 are the same material as dielectric layer 30, then the cross-sectional delineations illustrated in FIGS. 3-9 may no longer be evident.

Referring to FIG. 5, a chemical mechanical polish (CMP) is performed to planarize the surface of wafer 10 so that layer 30 is approximately planar with layer 20. Note that in the illustrated embodiment, dielectric material 30 remains exposed after planarization. Alternate embodiments may use any desired planarization process which planarizes layers 30 and 20 to be approximately planar.

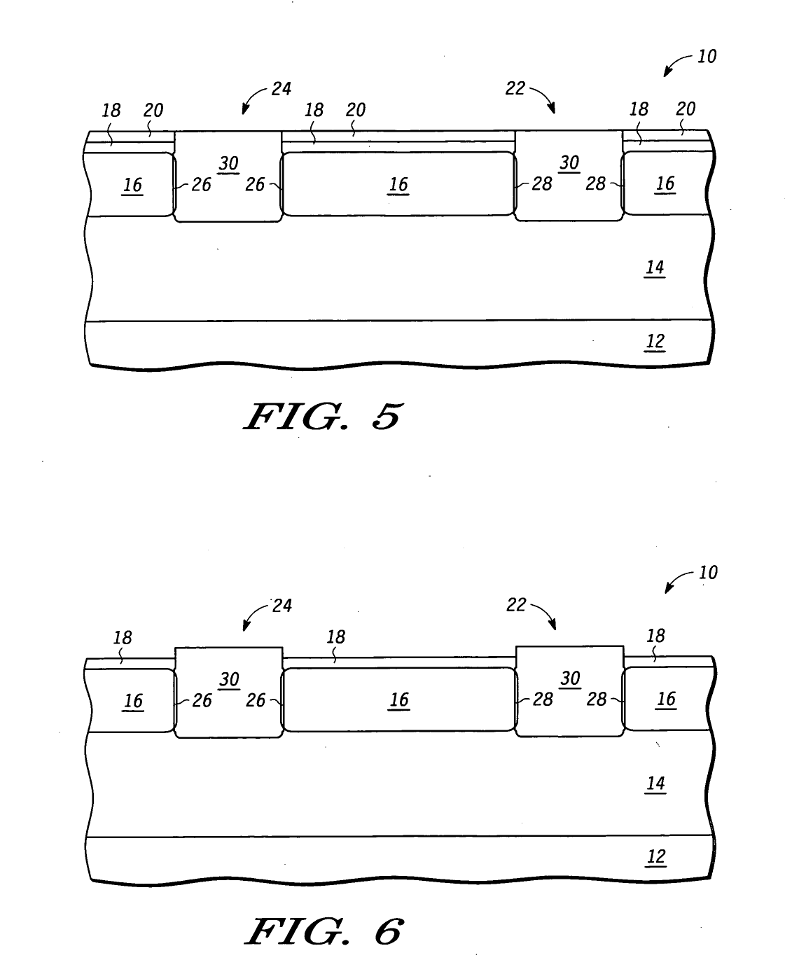

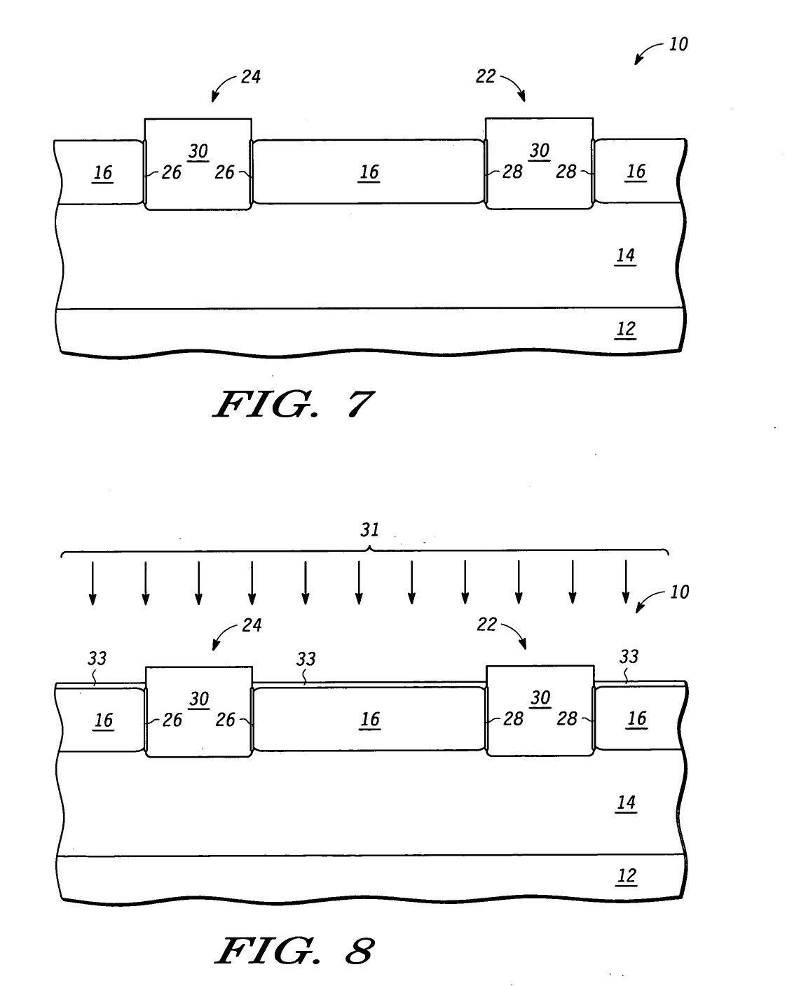

Referring to FIG. 6, nitride layer 20 is removed using one or more standard wet chemical etches, some of which comprise phosphoric acid.

Referring to FIG. 7, thermal oxide layer 18 is removed using one or more standard wet chemical etches, some of which comprise hydrofluoric acid.

Referring to FIG. 8, a sacrificial oxide layer 33 is formed overlying semiconductor layer 16 before an ion implantation 31 is performed. In one embodiment, oxide layer 33 may be grown to have a thickness in the range of 2-20 nm. Ion implantation 31 is used to dope portion of layer 16 in order adjust threshold voltages of transistors which will subsequently be formed in layer 16. In one embodiment, ion implantation 31 comprises the use of boron to dope selected portions of layer 16 to adjust the threshold voltage of n-channel transistor devices which will subsequently be formed in layer 16. In one embodiment, the dopant concentration of boron is in the range of 4 eˆ12 atoms percentimeter squared to 4 eˆ13 atoms percentimeter squared. In one embodiment, ion implantation 31 represents implanting a portion of semiconductor layer 16 (i.e. active region or well region) with a threshold voltage adjust implant comprising boron at a dosage of less than or equal to 2.5 eˆ13 atoms percentimeter squared. Note that for one embodiment, the implanted well region or active region is a region of an N-channel field effect transistor in an SRAM array.

Referring to FIG. 9, sacrificial oxide layer 33 is removed using one or more standard wet chemical etches, some of which comprise hydrofluoric acid. Note that divots 35 may be formed in trench isolation 30, 26 and divots 36 may be formed in trench isolation 30, 28. One problem with the formation of these divots 35, 36 is that subsequent processing steps may allow device gate material (e.g. polysilicon) to be formed in these divots 35, 36. The problem with depositing gate material in these divots 35, 36 is that a parasitic transistor may be formed at the interface between the active region 16 and the trench isolation 30, 26 and 30, 28. The deeper the divot 35, 36, the more the parasitic transistor may effect the behavior of adjacent devices in active region 16. As the depth of divots 35, 36 may vary significantly over the expanse of wafer 10, there may be a wide variation in the effect of the parasitic transistors due to divots 35, 36. Note that the effect of the parasitic transistor is more pronounced for adjacent transistors in active region 16 which have narrow active widths. Transistors used in SRAM cells generally have narrow active widths, and are thus more susceptible to threshold voltage variations.

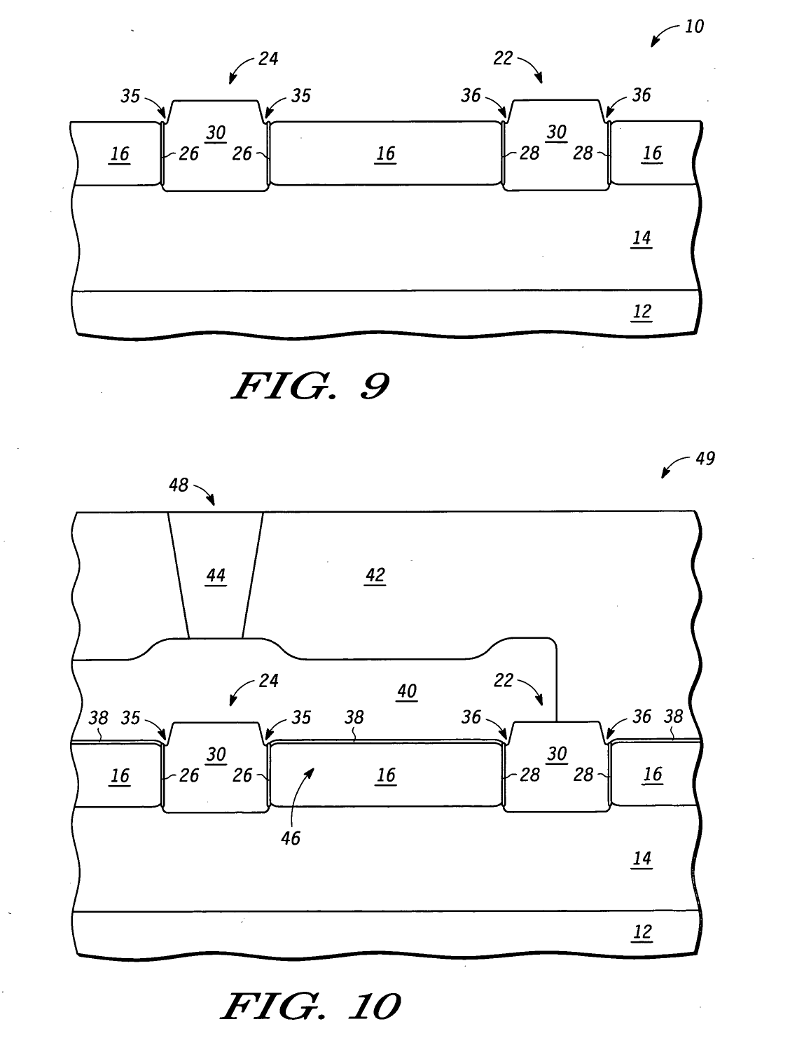

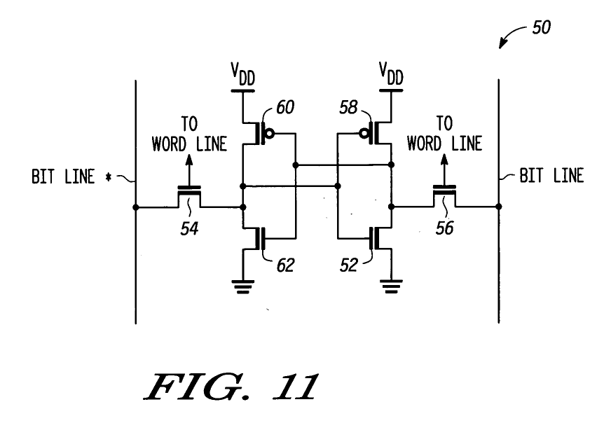

Referring to FIG. 10, the remaining steps to complete integrated circuit 49 are illustrated. In the illustrated embodiment, device 48 formed in active area 16 between trenches 22 and 24 may be a transistor. In one embodiment, a gate dielectric layer 38 if formed overlying layer 16. In one embodiment, gate dielectric layer 38 comprises an oxide which may be any desired thickness, and which may have a thickness in the range of 1.0-2.0 nm. A conductive layer 40 is formed overlying gate dielectric layers 38 and 30. In one embodiment, conductive layer 40 comprises polysilicon which may be any desired thickness, and which may have a thickness in the range of 50-200 nm. In another embodiment, one or more ion implantation steps may be used to introduce dopants into the polysilicon layer and increase the conductivity of the polysilicon layer. Next, an insulating layer 42 is formed overlying all of wafer 10. In one embodiment, insulating layer 42 includes one or more insulating layers comprising silicon nitride and/or silicon oxide, which may be any desired thickness, and which may have a total thickness after a layer 42 planarization in the range of 250-650 nm. Contact 44 is formed through insulating layer 42 to allow electrical contact to be made to conductive layer 40. In one embodiment, contact 44 comprises tungsten which is planarized along with layer 42.

FIG. 11 illustrates an SRAM cell 50 having transistors 52, 54, 56, 58, 60, and 62 wherein each transistor has a length (L) and a width (W). Note that one or more of transistors 52, 54, 56, 58, 60, and 62 illustrated in FIG. 11 may be formed in a same or similar manner to the transistor 48 illustrated in FIG. 10. In alternate embodiments, transistor 48 of FIG. 10 may be used in any type of circuit; SRAM cell 50 is just one example of a possible circuit that may use transistor 48. For example, an integrated circuit 49 (see FIG. 10) may comprise a plurality of transistors (e.g. transistor 48), each having a length (L) and a width (W). A one sigma variation of threshold voltages of the plurality of transistors is generally characterized as decreasing as a function of 1/((W*L)ˆ1/2)). However, if divots 35, 36 are too large and/or too deep, the one sigma variation of the threshold voltages of the plurality of transistors is dominated by the parasitic devices formed by the divots 35, 36, and no longer decreases as a function of 1/((W*L)ˆ1/2)), especially for transistor widths of less than or equal to 500 nm. Note that the symbol “*” represent a multiplication operation.

SRAM cells (e.g. 50 in FIG. 11) typically utilize narrow width transistors, and thus are more vulnerable to the negative parasitic effects caused by divots 35, 36. The increased variation in threshold voltages in SRAM cells (due to divots 35, 36) can lead to a reduction in the yield of an array of SRAM cells at low power supply voltages (e.g. VDD in FIG. 11). By using a high temperature densification to reduce the depth and height of divots 35, 36, the low voltage yield of an SRAM array can be improved. This yield enhancement can be used for any integrated circuit 49, but is particularly useful for integrated circuits 49 which have narrow width transistors.

Although the invention has been described with respect to specific conductivity types or polarity of potentials, skilled artisans appreciated that conductivity types and polarities of potentials may be reversed.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method of forming an integrated circuit, the method comprising:
forming a trench in a semiconductor layer, the semiconductor layer overlying an insulator layer of a semiconductor on insulator (SOI) wafer, wherein the trench extends at least to the insulator layer;
filling the trench with dielectric material;
heating the wafer at a temperature of at least 1100 C for at least 10 minutes after the filling the trench with dielectric material.

2. The method of claim 1 wherein the heating the wafer further includes heating the wafer in an ambient gas including argon.

3. The method of claim 1 wherein the heating densities the dielectric material.

4. The method of claim 1 further comprising planarizing the wafer wherein the dielectric material remains exposed after the planarization.

5. The method of claim 4 wherein the planarizing occurs subsequent to the heating.

6. The method of claim 1 wherein the dielectric material includes at least one of the group consisting of high density plasma oxide, TEOS, SOG (spin on glass), and high temperature deposited oxide.

7. The method of claim 1 wherein a trench isolation includes the dielectric material, the method further comprising:
forming an active region of a transistor in the semiconductor layer adjacent to the trench isolation.

8. The method of claim 1 wherein a trench isolation includes the dielectric material, the method further comprising:
forming a gate structure of a transistor, wherein the gate structure extends at least partially over the trench isolation.

9. The method of claim 1 wherein the heating includes heating the wafer at a temperature of at least 1150 C for at least 10 minutes.

10. The method of claim 1 wherein the heating includes heating the wafer at a temperature of at least 1100 C for at least 15 minutes.

11. The method of claim 1 further comprising:
implanting an active region of the semiconductor layer with a threshold voltage adjust implant including boron at a dosage of less than or equal to 2.5 eˆ13 atoms percentimeter squared;
wherein the integrated circuit includes an SRAM array, wherein the active region is an active region of an N-channel field effect transistor of the SRAM array.

12. The method of claim 1 wherein:
the integrated circuit includes a plurality of transistors, each having a length (L) and a width (W);
a trench isolation includes the dielectric material, the trench isolation is adjacent to an active region of a transistor of the plurality of transistors;
a one sigma variation of a threshold voltage of the plurality of transistors is generally characterized as decreasing as a function of 1/((WL)ˆ1/2)) for widths of less than or equal to 500 nanometers.

13. A method of making an integrated circuit, the method comprising:
forming a trench in a semiconductor material of a wafer;
filling the trench with dielectric material;
heating the wafer at a temperature of at least 1100 C for at least 10 minutes in an ambient gas including argon after the filling the trench with dielectric material;
wherein a trench isolation includes the dielectric material.

14. The method of claim 13 wherein after the heating, the method further comprises planarizing the wafer, wherein the dielectric material remains exposed after the planarization.

15. The method of claim 13 wherein the dielectric material includes at least one of the group consisting of high density plasma oxide, TEOS, and high temperature deposited oxide.

16. The method of claim 13 wherein the heating densifies the dielectric material.

17. The method of claim 13 wherein the wafer is characterized as a semiconductor on insulator (SOI) wafer and includes an insulator layer, the semiconductor material is located over the insulator layer.

18. The method of claim 13 wherein the heating includes heating the wafer at a temperature of at least 1150 C for at least 15 minutes.

19. The method of claim 13 wherein the trench isolation includes a thermal liner material formed on a sidewall of the trench.

20. The method of claim 13 wherein the trench has a depth of 150 nanometers or less.

21. A method of forming an integrated circuit, the method comprising:
forming a trench in a semiconductor layer, the semiconductor layer overlying an insulator layer of a semiconductor on insulator (SOI) wafer, wherein the trench extends at least to the insulator layer;
filling the trench with dielectric material;
heating the wafer at a temperature of at least 1100 C for at least 10 minutes after the filling the trench with dielectric material;
planarizing the wafer, wherein the dielectric material remains exposed after the planarization;
wherein a trench isolation includes the dielectric material;
forming a transistor including an active region in the semiconductor layer adjacent to the trench isolation.
